(19) United States
(12) Patent Application Publication
(10) Pub. No.: US 2005/0274965 A1
(43) Pub. Date: Dec. 15, 2005

(54) Sterilizing method, system, and device utilizing ultraviolet light emitting diodes powered by direct current or solar power in a recreational vehicle or marine environment

(76) Inventors: David L. Phillips, Santa Ana, CA (US); William B. McDonough, Huntington Beach, CA (US); Richard W. Lee, Mission Viejo, CA (US)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(21) Appl. No.: 11/145,536

(22) Filed: Jun. 2, 2005

Related U.S. Application Data
(60) Provisional application No. 60/576,413, filed on Jun. 2, 2004.

(51) Int. Cl. H01L 29/22; H01L 33/00

(52) U.S. Cl. 257/94

(57) ABSTRACT

A method, system, and device for sterilizing a medium such as gas or liquid, by arranging light sources in relation to a container containing the medium, and by then generating ultraviolet (UV) radiation for destroying bacteria or other microorganisms in the medium. The microorganisms are preferably destroyed by interacting with the UV radiation, thus damaging the DNA of the organisms and their ability to reproduce. The light sources, such as light emitting diodes, may be powered with a low voltage source as a primary power supply. The system or device include means, such as a sleeve, for situating the LEDs with respect to the container.

### RELATED APPLICATIONS

The present application claims priority to U.S. Provisional Application No. 60/576,413 filed Jun. 2, 2004.

### FIELD OF THE INVENTION

The present invention relates to sterilization using ultraviolet light.

### BACKGROUND OF THE INVENTION

There are many “non-chemical” technologies to reduce or destroy harmful bacteria in water, air, and food available. The effects of high intensity short wave (257 nM wavelength) ultra-violet radiation have been well documented and employed in products for over 25 years. This short-wave UV radiation does not “kill” harmful bacteria instantly, but it does damage the DNA of the bacteria sufficiently that they do not reproduce. Since the lifespan of a bacteria is typically only a few hours, with no reproduction the bacteria simply ceases to exist after being continuously exposed to the UV radiation. It is important to note that the energy from the short-wave UV light is the only thing in contact with the water and that is solely the germicidal agent. A small amount of ozone may be produced because the nature of intensity of the light radiation, but this is only a small byproduct of the intense light energy.

UV devices on the market have been used in the pool/spa industry, the food industry, and in consumer applications as air sterilizers. These devices were first implemented using UV lights or “germicidal” lamps whose radiation was optimized in the 240 to 300 nanometers (nM) wavelengths (UV), which is in the “blue” end of the visible spectrum to invisible. This is the “highest energy” of visible light. Later, generation of ozone by emulation of “lightning”, i.e., spark discharge via a high-voltage generator circuit and a spark gap have been employed. This ozone is released directly into the air and pumped into a liquid such as water, or circulated in the air to disperse the ozone molecules.

Unfortunately, these prior art devices have serious limitations. The UV lamp sources require a relatively expensive bulb, along with a ballast transformer similar to fluorescent lamps. These bulbs have a limited life of a few thousand hours, up to perhaps 10,000 hours. Also, they are physically rather large and generate significant amounts of heat, which must be dissipated into the air. The coronal discharge (CD) devices utilize electronic circuits similar to the ignitions systems in automobiles to generate high voltages via a step-up transformer. While these devices have relatively unlimited lifetimes, they are subject to failure in high-humidity environments and are dangerous in explosive environments because they generate high voltage sparks which must be contained in a metal chamber.

However, it is well documented that ozone in large concentrations is damaging to humans. It irritates and damages membranes in the nose and lungs. In small concentrations it gives unpleasant, burning sensations in the nose and lungs; in large concentrations, it is fatal. The EPA and OSHA has well established concentrations level considered safe for humans and large users of ozone-based systems, such as water purification plants, must continuously monitor their concentrations.

Because of the ease of generating large concentrations of ozone at low cost, these ozone devices have surpassed UV devices in recent popularity in the market. However, because of the inherent health dangers of ozone especially to individuals with Asthma and other respiratory problems, we are now seeing a move to limit or prohibit such devices in the air purification industry. Thus we feel that inherent safety of UV will increase in popularity.

Some particular prior art patents will now be briefly discussed, including Kool et al. (U.S. Pat. No. 6,245,229) and Beitzel '970 (U.S. Pat. No. 4,274,970). These two patents each disclose using a UV source to destroy microorganisms in a medium. In Kool et al. '229, the UV source is an elongated lamp powered “in a conventional manner,” while in Kool the UV source forms part of a UV subassembly and includes a power supply having a transformer. Other patents showing variation of treating a medium using UV include Last (U.S. Pat. No. 4,141,830) which uses ultra violet lamps to treat a medium flowing through a jacket; as well as Beitzel '660 (U.S. Pat. No. 4,273,660) which uses a UV lamp and Hur et al. (U.S. Pat. No. 6,762,414) which uses electrodeless UV lamps. However, all of these patents require relatively large and inefficient UV sources.

Some prior art patents disclose LED UV sources. For example, Ganz (U.S. Pat. No. 6,764,501) discloses using a UV LED source having a wavelength of 200-400 nM to treat atherosclerotic buildup in veins or arteries by destroying pathenogenic microorganisms. Maas et al. (U.S. Pat. No. 6,402,347) and Mueller-Mach et al. (U.S. Pat. No. 6,630,691) also disclose techniques for generating UV light using LEDs. However, none of these patents disclose or suggest to use an LED UV source to destroy bacteria or microorganisms in a medium flowing though a container.

### SUMMARY OF THE INVENTION

The present invention makes use of recent technological advances in solid state light-emitting diodes (LEDs) which are now capable of generating light in the sub-400 nM wavelengths commonly known as ultraviolet (UV). These LEDs are manufactured using the same general techniques of other LEDs that emit red, green, yellow, and more recently, white, blue and infrared spectrum. They share the advantages of this technology, such as extremely long life (10,000 to 100,000 hours or more), very small size, high-energy efficiency, rugged vibration resistant design, and low voltage DC operation. Just as for the other colors of light, these individual LEDs do not produce anything close to the same light output per device as an incandescent or fluorescent light source. However, due to their small size and power consumption, they may be combined into arrays of multiple LEDs in series parallel to produce light outputs, which begin to approach the conventional methods of generation.

By combining arrays of these LEDs surrounding a small tube of water or air which is circulated via a pump, it becomes possible to generate an efficient source of UV radiation which can destroy bacteria and other microorganisms in water supplies in vehicles in which a low voltage battery source is the prime power supply. Such vehicles may include sports utility vehicles (SUV), recreational vehicles (RV), boats or other marine vehicles, military units in the field, and long-haul truckers. The invention may be used in connection with refrigerators, portable coolers, aquariums, sinks, water fountains, and restrooms.

The present invention features a method and apparatus for sterilizing a medium. The method includes steps of arranging one or more light emitting diodes (LEDs) in relation to a container having a medium therein, generating ultraviolet (UV) radiation for destroying bacteria and other suitable microorganisms in the medium, and powering the one or more light emitting diodes (LEDs) with a low voltage source as a primary power supply.

The low voltage source includes a battery source in a range of about 10-42 volts, such as a battery for an recreational vehicle, boat, truck, SUV, etc. In operation, the generation of the UV radiation produces intense light that destroys the bacteria and other suitable microorganisms in the medium. In one embodiment, the one or more light emitting diodes take the form of an array of multiple LEDs in a series relationship, a parallel relationship, or some combination thereof, plus a reflector lens to concentrate the LED UV light; the container for the medium may take the form of a tube having the medium circulated therein by a pump or other suitable circulating device, with the array of multiple LEDs surrounding the tube at one or more locations. The one or more light emitting diodes (LEDs) generate light having a wavelength in the sub-400 nanometer (nM) range. The medium includes air, water or some other suitable medium.

It should be noted that the present invention need not utilize light emitting diodes (LEDs), and can instead function (in some embodiments of the present invention) using one or more conventional bulbs, such as a mercury-vapor bulb. Additionally, it should be emphasized that the present invention discloses a way to clean a medium by circulating the medium by a light source at regular intervals, even before a user seeks access to the medium. The medium could, of course, be further cleaned in response to a user access attempt (e.g. when a user turns on a spigot). Thus, the present invention includes a complete system for low voltage applications that will utilize a pump to circulate a gas or a liquid (such as water) from holding tanks through the system and back into the holding tanks, employing a UV sterilizing method (LEDs or Bulbs). It is anticipated that LEDs will be the primary source of UV once they become fully available on the market, at wavelengths that are used for suitable for killing bacteria. The LEDs can then be sandwiched between a circulating container (such as a transparent or translucent pipe) and a sleeve fitted around the pipe.

### BRIEF DESCRIPTION OF THE DRAWINGS

FIG. 1 is a schematic showing the circuitry of an embodiment of the present invention.

FIG. 2 is a block diagram showing a system according to an embodiment of the present invention.

FIG. 3 depicts a device according to an embodiment of the present invention.

FIG. 4 is a flow chart showing a method according to an embodiment of the present invention.

### DETAILED DESCRIPTION OF THE INVENTION

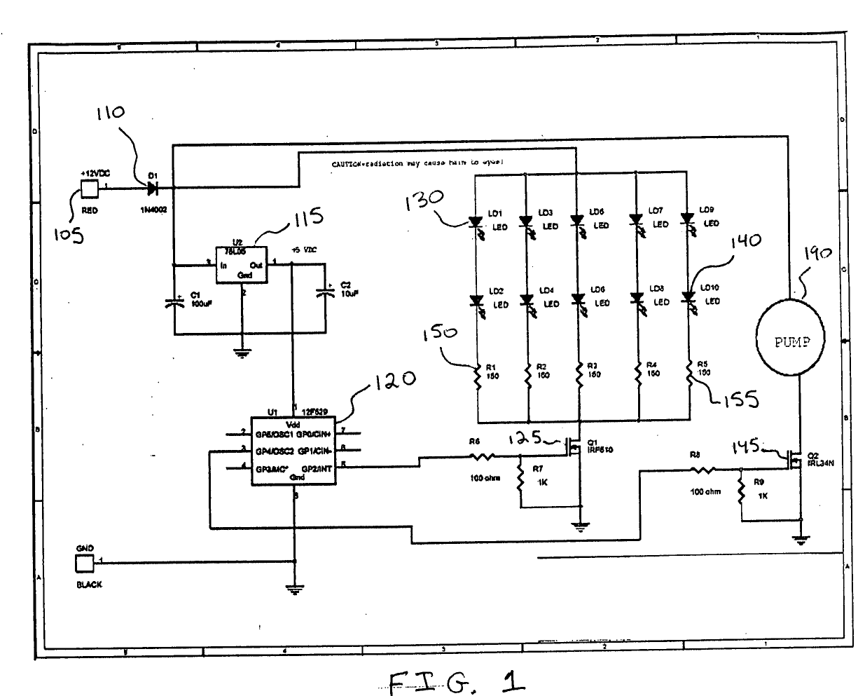

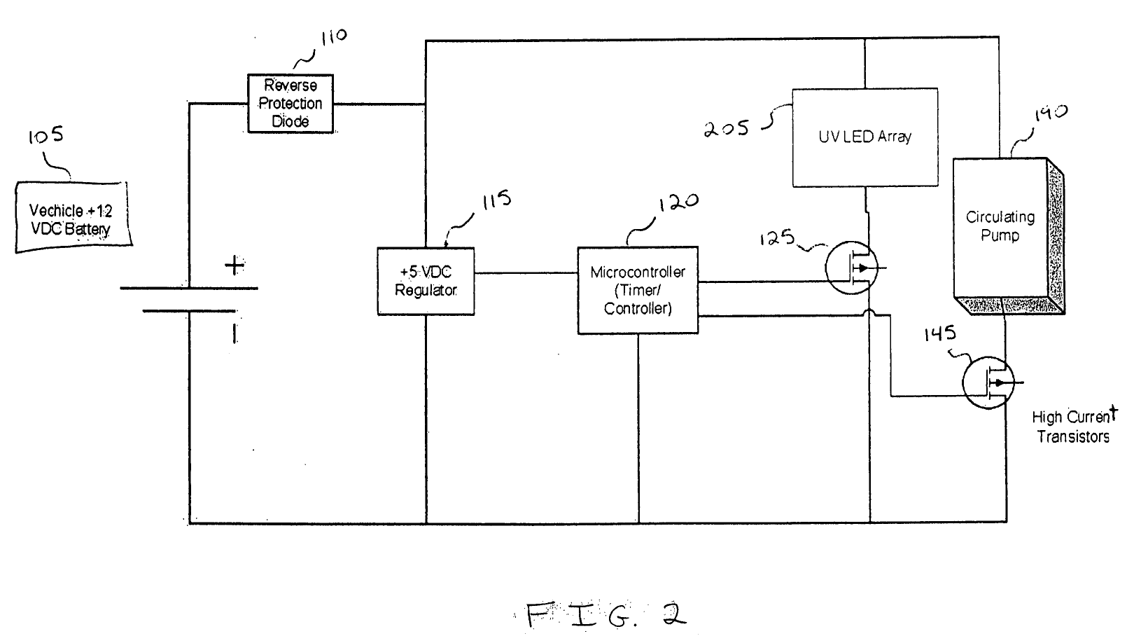

Referring to the schematic diagram shown in FIG. 1 and the corresponding block diagram shown in FIG. 2, the unit will run directly from the power source VDC supply 105 of a vehicle such as an RV, boat, truck, SUV, or the like. Diode 110 is a simple rectifier diode used to prevent damage to the circuit due to reverse polarity wiring. Device 115 is a voltage regulator (such as a 78L05), which down-regulates this to a suitable voltage for use by device 120, a single chip microcontroller such as a PIC 12F629 device, which is the main timer-controller in the system. Transistor 125 is a medium current N-channel MOSFET device used to turn on a plurality of UV LEDs 130 through 140 connected in series-parallel. Transistor 145 is a high-current MOSFET used to turn on a circulating pump. Resistors 150 through 155 are “equalizing resistors” to allow the series-parallel connection of large numbers of LEDs. This scheme can be extended out to a large number “N” of series-parallel LEDs and is not limited to the 20 shown in FIG. 1.

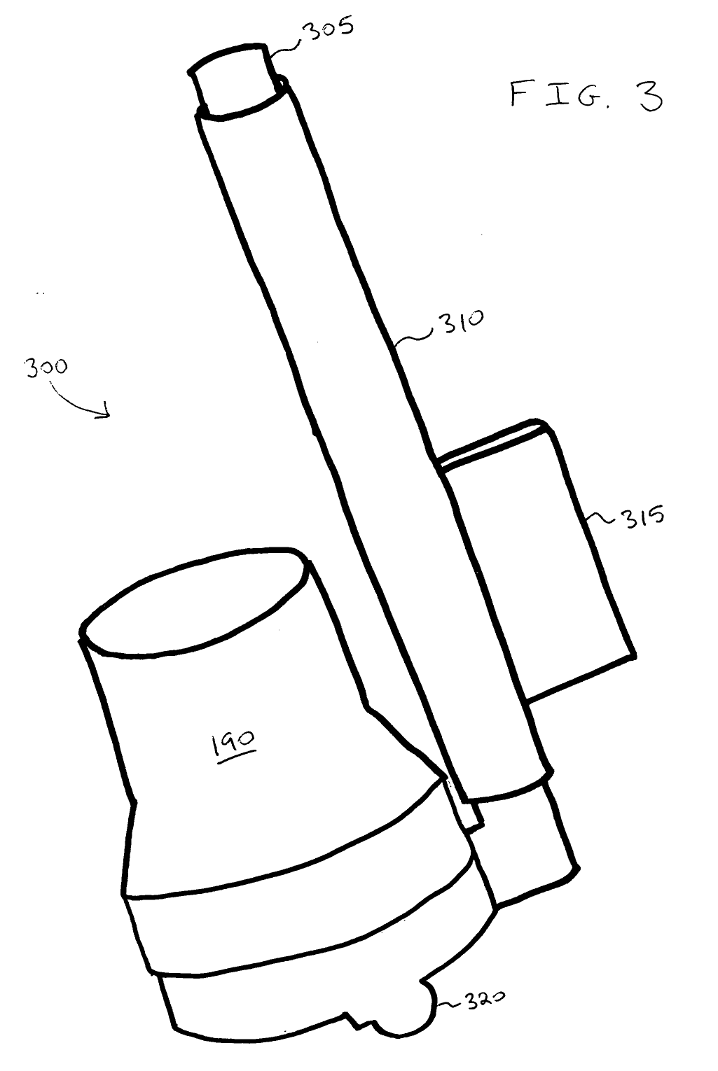

Device 120 acts as a timer-controller to activate the LEDs and pump 190 on a timed basis (e.g. 2 hours ON, every 12 hours) to insure that a sufficient amount of water is “treated” by exposure to the UV. This water is passed through the mechanism 300 shown in FIG. 3, to bring it from an inlet 320 through a small diameter tube 305 in very close contact with the UV LED array 205 to expose the water to a high concentration of UV radiation. The LED array 205 is situated with respect to the containing tube 305 by sleeve 310. The LED and pump circuitry are located adjacent to the sleeve, in a circuitry unit 315.

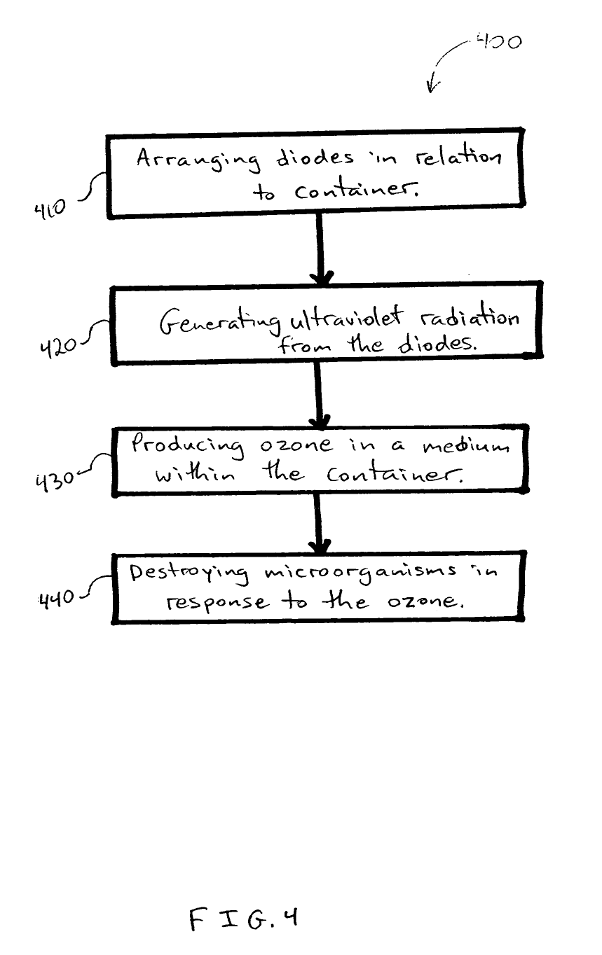

With the help of the flow chart in FIG. 4, the method 400 of the present invention can be further appreciated. Light emitting diodes are arranged 410 in relation to a container such as a pipe, for instance by sandwiching the diodes between the container and a sleeve.

It is to be understood that all of the present figures, and the accompanying narrative discussions of best mode embodiments, do not purport to be completely rigorous treatments of the method, system, and device under consideration. A person skilled in the art will understand that the steps of the present application represent general cause-and-effect relationships that do not exclude intermediate interactions of various types, and will further understand that the various structures described in this application can be implemented by a variety of different combinations of hardware, software, and other elements which need not be further detailed herein.

1. A method for sterilizing a medium, characterized in that the method comprises:
arranging one or more light sources in relation to a container having a medium therein, and
generating ultraviolet (UV) radiation for destroying bacteria or other microorganisms in the medium.

2. A method according to claim 1, wherein the one or more light emitting diodes include an array of multiple light emitting diodes (LEDs) in a series relationship, a parallel relationship, or some combination thereof.

3. A method according to claim 1, wherein the container includes a tube having the medium circulated therein by a pump.

4. A method according to claim 3, wherein the one or more light emitting diodes surround the tube at one or more locations.

5. A method according to claim 1, wherein the generation of the UV radiation is focused into the medium.

6. A method according to claim 1, wherein the medium is gas or liquid.

7. A method according to claim 1, wherein the one or more light sources generate light having a wavelength in the sub-400 nanometer (nM) range.

8. A method according to claim 1, wherein a low voltage source powers the light sources, and wherein the low voltage source is a battery source substantially in a range of 10-42 volts.

9. The method of claim 1, wherein the medium is circulated in the container by a pump, on a regular schedule, from at least one holding tank toward the light sources, and then back to the at least one holding tank.

10. A device or system for sterilizing a medium, comprising:
one or more light sources that are arranged in relation to a container that is for containing a medium therein; and
means for situating said light sources with respect to the container;
wherein the light sources are configured to provide ultraviolet (UV) radiation for destroying bacteria or other microorganisms in the medium.

11. A device or system according to claim 10, wherein the one or more light sources are light emitting diodes (LEDs) arrayed in a series relationship, a parallel relationship, or some combination thereof.

12. A device or system according to claim 10, wherein the container includes a tube having the medium circulated therein by a pump.

13. A device or system according to claim 12, wherein the one or more light emitting diodes (LEDs) surround the tube at one or more locations.

14. A device or system according to claim 10, wherein the radiation is focussed into the medium.

15. A device or system according to claim 10, wherein the medium is gas or liquid.

16. A device or system according to claim 10, wherein the one or more light sources generate light having a wavelength in a sub-400 nanometer (nM) range.

17. A device or system according to claim 10, further comprising a battery substantially in a range of 10-42 volts, for powering said one or more light source.
